(19) United States
(12) Patent Application Publication
(10) Pub. No.: US 2021/0210653 A1
(43) Pub. Date: Jul. 8, 2021

(54) GROWTH SUBSTRATE FOR FORMING OPTOELECTRONIC DEVICES, METHOD FOR MANUFACTURING SUCH A SUBSTRATE, AND USE OF THE SUBSTRATE, IN PARTICULAR IN THE FIELD OF MICRO-DISPLAY SCREENS

(71) Applicant: Soitec, Bemin (FR)

(72) Inventors: David Sotta, Grenoble (FR); Olivier Ledoux, Grenoble (FR); Olivier Bonnin, Bresson (FR); Jean-Marc Bethoux, La Buisse (FR); Morgane Logiou, Crolles (FR); Raphaél Caulmilone, Saint Pancrasse (FR)

(21) Appl. No.: 16/069,469

(22) PCT Filed: Mar. 14, 2018
(86) PCT No.: PCT/FR2018/050606

§ 371 Date: Jul. 11, 2018

(30) Foreign Application Priority Data
Mar. 17, 2017 (FR) 1752230
Mar. 13, 2018 (FR) 1852155
Mar. 13, 2018 (FR) 1852156

(51) Int. Cl. H01L 33/00

(52) U.S. Cl. CPC H01L 33/007

(57) ABSTRACT

A growth substrate for forming optoelectronic devices comprises a growth medium and, arranged on the growth medium, a first group of crystalline semiconductor islands having a first lattice parameter and a second group of crystalline semiconductor islands having a second lattice parameter that is different from the first. Methods may be used to manufacture such growth substrates. The methods may be used to provide a monolithic micro-panel or light-emitting diodes or a micro-display screen.

### CROSS-REFERENCE TO RELATED APPLICATIONS

This application is a national phase entry under 35 U.S.C. § 371 of International Patent Application PCT/FR2018/050606, filed Mar. 14, 2018, designating the United States of America, which claims the benefit under Article 8 of the Patent Cooperation Treaty to French Patent Application Serial Nos. 18/52155 and 18/52156, both filed Mar. 13, 2018, and French Patent Application Serial No. 17/52230, filed Mar. 17, 2017. This application is also a continuation-in-part of U.S. patent application Ser. No. 15/491,827, filed Apr. 19, 2017, pending.

### TECHNICAL FIELD

This application relates to a growth substrate for forming optoelectronic devices as well as a method for manufacturing this substrate. It also applies to the use of this substrate for the collective manufacture of devices having optoelectronic properties that can be different from one another. The disclosure can particularly be applied in the field of micro-display screens.

### BACKGROUND

The documents EP2151852 and EP2151856 disclose a technology intended to form, on a substrate, islands of relaxed or partially relaxed crystalline semiconductor material. These islands can be used for the collective manufacture of light-emitting diodes (LEDs), as explained in detail in document EP2865021, for example.

Multiple products combine LEDs emitting at various wavelengths to form a colored light point. This is, among others, the case for display screens that enable an image consisting of pixels to be formed, each pixel combining a red, a green, and a blue LED, whose emission can be controlled individually to form a light point of the selected color by combining light emissions.

The LEDs that are combined to form the pixel are generally not manufactured from the same materials and using the same technologies. Thereby, blue or green LEDs may consist of nitride (with the general formula InGaN) and red LEDs of phosphide (with the general formula AlGaInP). Manufacturing a screen involves the assembly of the diodes, one by one, to form the pixels of the final device, e.g., using a pick-and-place technique.

Since the materials do not have the same properties, the characteristics pertaining to the ageing, thermal/electrical behavior, and/or efficiency of the devices that use them are generally very different. These variabilities must be taken into account when designing a product that includes LEDs consisting of different materials, which may sometimes render the design very complex.

Other solutions provide for forming the pixels from diodes that are all identical, manufactured on the same substrate and/or using the same technology. Monolithic micro-LED panels having a reduced size and a high resolution can then be realized. By way of example of such a realization, one may refer to the document entitled “360 PPI Flip-Chip Mounted Active Matrix Addressable Light Emitting Diode on Silicon (LEDoS) Micro-Displays,” Zhao Jun Liu et al., Journal of Display Technology, April 2013. The light radiation emitted by the micro-panel's LEDs can be chosen in the ultraviolet range and selectively converted, from one diode to another, to various wavelengths in order to correspond to red, green, and blue light emissions so as to form a color screen. This conversion can be achieved by placing a phosphorescent material on the emitting face of the LEDs. However, the conversion consumes light energy, which reduces the quantity of light emitted by each pixel and, thus, the efficiency of the display device. It also requires dispensing the phosphorescent materials on the emitting surfaces of the LEDs, which renders the manufacturing method of these micro-panels more complex. Moreover, the size of the particles of phosphorescent material may exceed the desired dimension of the bright pixels, which does not always allow for this solution to be used.

In order to overcome the limitations discussed above, it would be desirable to be able to simultaneously manufacture, on the same substrate, using the same technology, LEDs capable of emitting in different wavelengths. More generally, it would be advantageous to collectively manufacture devices having optoelectronic properties that are different one from another.

### BRIEF SUMMARY

In view of achieving one of these goals, in a first aspect, the disclosure provides a method for manufacturing a plurality of crystalline semiconductor islands having a variety of lattice parameters.

The method includes a step aimed at providing a relaxation substrate comprising a medium, a flow layer disposed on the medium and, arranged on the flow layer, a plurality of crystalline semiconductor islands having the same initial lattice parameter, and comprising a first group of islands having a first lateral expansion potential and a second group of islands having a second lateral expansion potential that is different from the first.

It also includes a step aimed at heat-treating the relaxation substrate at a temperature that is higher than or equal to the glass transition temperature of the flow layer to cause differentiated relaxation of the islands of the first and second groups, the lattice parameters of the first group of relaxed islands and of the second group of relaxed islands then have different values.

According to other advantageous and non-restrictive characteristics of the disclosure, taken either separately or in any technically feasible combination:
before the heat treatment step, the first group of islands has a first strain level and the second group has a second strain level that is different from the first;
the step in which the relaxation substrate is provided includes the following:
   the formation on a base substrate of a stack of elementary crystalline semiconductor layers having a first area and a second area that have different strain levels;
   the transfer of at least part of the stack to the medium;
   the execution of trenches on the stack to form the islands of the first group of islands in the first area and to form the islands of the second group of islands in the second area;
the execution of trenches in the stack is performed after the transfer to the medium;
the formation of the stack on the base substrate includes the following:
   the formation of a plurality of pseudomorphic elementary layers having different compositions;
   localized removal of part of the elementary layers to define the first area and the second area;
the flow layer consists of a first group of blocks having a first viscosity at the relaxation temperature and a second group of blocks having a second viscosity that is different from the first at the relaxation temperature, the islands of the first group of islands being arranged on the blocks of the first group of blocks and the islands of the second group of islands being arranged on the blocks of the second group of blocks;
the step in which the substrate is provided includes the following:
   the formation on the medium of a first flow layer made of a first material;
   the formation of at least one recess in the first flow layer;
   the deposition of a second flow layer made of a second material on the first flow layer and in the recess in view of forming a stack of flow layers;
   the planarization of the stack to eliminate the second layer, except for in the recess, and to form the first group of blocks and the second group of blocks;
the provision step includes the following:
   forming the plurality of crystalline semiconductor islands on the flow layer, the plurality of islands having a same initial strain level;
   selectively treating the strained islands so as to form the first group of strained islands and the second group of strained islands;
the selective treatment includes the formation of a stiffening layer having a first thickness on the first group of strained islands and having a second thickness on the second group of strained islands;
the selective treatment includes the formation, on the first group of strained islands, of a stiffening layer formed from a first material and the formation, on the second group of strained islands, of a stiffening layer formed from a second material that is different from the first;
the selective treatment includes the reduction in thickness of the strained islands of the first group and/or of the strained islands of the second group, so that they have different thicknesses;
the heat treatment is performed at a temperature ranging from 400° C. to 900° C.;
the crystalline semiconductor islands (3a, 3b) are composed of III-N material;
the manufacturing method includes a step during which relaxed islands of the first group and relaxed islands of the second group are transferred to a growth medium.

In another aspect, the disclosure provides a growth substrate for forming optoelectronic devices comprising a growth medium, an assembly layer and, arranged on the assembly layer, a first group of crystalline semiconductor islands having a first lattice parameter and a second group of crystalline semiconductor islands having a second lattice parameter that is different from the first.

According to other advantageous and non-restrictive characteristics of this growth substrate, taken either separately or in any technically feasible combination:
the growth medium is a silicon or sapphire wafer;
the crystalline semiconductor islands are composed of InGaN;
each island of the first group is placed next to an island of the second group to form a pixel;
the assembly layer includes at least one dielectric material.

In yet another aspect, the disclosure provides a method of using the growth substrate for the collective manufacture of a plurality of optoelectronic devices comprising active layers of various compositions, the method including the steps for providing the growth substrate and for exposing the growth substrate to an atmosphere comprising an initial concentration of an atomic element to form a first active layer incorporating the atomic element in a first concentration on the islands of the first group and to form a second active layer incorporating the atomic element in a second concentration, which is different from the first, on the islands of the second group.

According to other advantageous and non-restrictive characteristics of this use, taken either separately or in any technically feasible combination:
the atmosphere is formed from precursor gases including TMGa, TEGa, TMIn, and ammonia;
the atomic element is indium;
the first and the second active layers comprise an n-doped InGaN layer, a multiple quantum well, a p-doped InGaN or GaN layer.

### BRIEF DESCRIPTION OF THE DRAWINGS

Further characteristics and advantages of the disclosure will be clear from the following detailed description, made in reference to the accompanying figures, among which:

FIGS. 1a, 1b and 1c schematically show cross-sections and a top view of growth substrates according to the disclosure;

FIGS. 2a, 2b, and 2c show an example of how the crystalline semiconductor islands can be arranged and distributed on the surface of a growth medium;

FIGS. 3a to 3e show a first method for manufacturing a growth substrate according to the disclosure;

FIGS. 4a to 4c show a second method for manufacturing a growth substrate according to the disclosure;

FIGS. 5a to 5d show a method for producing a flow layer comprising blocks of different viscosity;

FIGS. 6a to 6m show a third method for manufacturing a growth substrate according to the disclosure.

### DETAILED DESCRIPTION

### Growth Substrate

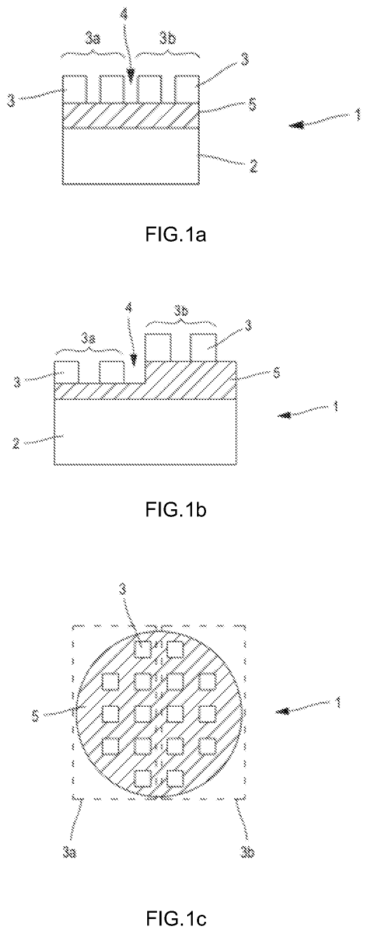

In a first aspect, the present disclosure relates to a growth substrate 1 for forming optoelectronic devices. FIGS. 1a and 1b schematically show a cross-section of two growth substrates according to the disclosure. FIG. 1c is a top view of these substrates. The growth substrate 1 is intended to be placed in deposition equipment, such as an epitaxy frame, in order to form active layers of optoelectronic components on the exposed surface of the substrate 1. The substrate 1 can also serve as mechanical support allowing for devices to be manipulated during further manufacturing steps (formation of electrical contacts, isolation of one device from the other, etc.) leading to the achievement of a functional device.

The growth substrate 1 includes a growth medium 2. This can be a circular wafer of materials, e.g., silicon or sapphire, of standardized dimensions, e.g., 2 inches (50 mm), 4 inches (100 mm) or even 200 mm in diameter. However, the disclosure is in no way restricted to these dimensions or this shape.

The nature of the growth medium 2 is generally selected so as to be able to withstand treatments (such as depositions, heat treatment, etc.) implemented when manufacturing the actual growth substrate 1 and when manufacturing optoelectronic devices. Preferably, the growth medium 2 has a thermal expansion factor similar or close to that of the materials that will form the useful layer of the optoelectronic device so as to limit the significant strains that could damage these devices following their production.

The growth substrate 1 also comprises a plurality of crystalline semiconductor islands 3 (hereinafter simply referred to as “island(s)”), placed on the growth medium 2. Each island 3 is intended to carry the active layers of an optoelectronic device, such as an LED, a laser or a photovoltaic cell. To this end, the islands 3 can be made of III-N materials. For the formation of nitride-based LEDs, the islands 3 can thus consist of wurtzite structure GaN or InGaN, the axis c of which is perpendicular to the surface, and in which the proportion of indium may vary between 0% and 20% and, in particular, between 1.5% and 8%.

The term “island” refers to a block of material that is entirely separate from the other islands arranged on the growth medium 2. The term “crystalline” means that the atoms making up an island 3 are assembled in an orderly manner to form a block of monocrystalline material, the block may nevertheless comprise arrangement defects such as dislocation, slip plane or point defect.

The islands 3 are separated one from another by trenches 4. These trenches may have a lateral dimension, separating two islands 3, ranging from 0.1 to 50 microns, or from 1 to 50 microns, and typically to the order of 2 to 20 microns. Each island has a relatively reduced size in relation to the growth substrate, which may, for example, stretch from 1 micron to 1 mm in its largest dimension, depending on the intended final application. The surface of the islands 3 may range from 1 μm² or 4 μm² to 1 mm², and preferably from 25 μm² to 400 μm². Each island 3 can have any shape, e.g., circular, square, triangular, hexagonal or rectangular, when viewed from above. Its thickness is typically less than 200 nm, in particular, when it consists of InGaN. The islands 3 can all be of identical or different shapes and dimensions.

The islands 3 do not all have the same lattice parameter. Thus, a first group of islands 3a has a first lattice parameter and a second group of islands 3b has a second lattice parameter that is different from the first.

In the variant of growth medium 1 shown in FIG. 1a, and as will become apparent in the description of the manufacturing method of this substrate, all the islands 3 consist of the same material. Since the materials of the islands 3 are identical to each other, the existence of a difference in the lattice parameter indicates the existence of a different stain state between the islands 3 that make up the two groups 3a and 3b.

In the variant of growth medium 1 shown in FIG. 1b, the materials of the islands 3 are not identical to each other from one group to the next. Moreover, the state of strain of the islands 3 making up the two groups of islands 3a, 3b may also be different from one group to the next. Accordingly, the two groups of islands 3a, 3b have different lattice parameters.

The variety of the lattice parameters for the islands 3 of the growth substrate 1 will be used advantageously to collectively manufacture optoelectronic devices that have distinct light properties, using a single manufacturing technology and a single growth substrate.

As an example, on the first group of islands 3a that has the first lattice parameter, it will be possible to form a first LED that directly emits at a first wavelength, e.g., in the green range, and on the second group of islands 3b that has the second lattice parameter, a second LED directly emitting at a second wavelength, e.g., in the blue range. The terms “directly emitting” are used to indicate that the emission corresponds to the light radiations emitted by an LED's active layers (quantum wells), without needing to use phosphorus conversion.

It may also be provided that the growth substrate 1 comprises at least one third group of islands, this third group of islands having a third lattice parameter that is different from the first and the second. More generally, the growth substrate may comprise any number of island groups, each group being formed by islands having a lattice parameter that is different from that of the islands belonging to other groups. In this way, it will be possible to obtain a growth substrate 1 allowing the formation of LEDs emitting in the range of red, green, blue, and infrared wavelengths on the same substrate using a single technology.

The distribution and arrangement of the groups of islands 3a, 3b on the surface of the growth medium 2 is not an essential characteristic of this aspect of the disclosure, and all possible distributions and arrangements may be considered. They may sometimes be dictated by the application under consideration.

A first example of distribution and arrangement of the first and second groups of islands 3a, 3b on the surface of the medium 2 has thus been represented in FIGS. 1a and 1b. In this example, the first group of islands 3a occupies a first area of the medium 2 and the second group of islands 3b a second area of the medium 2, which are separate one from the other and adjacent to each other.

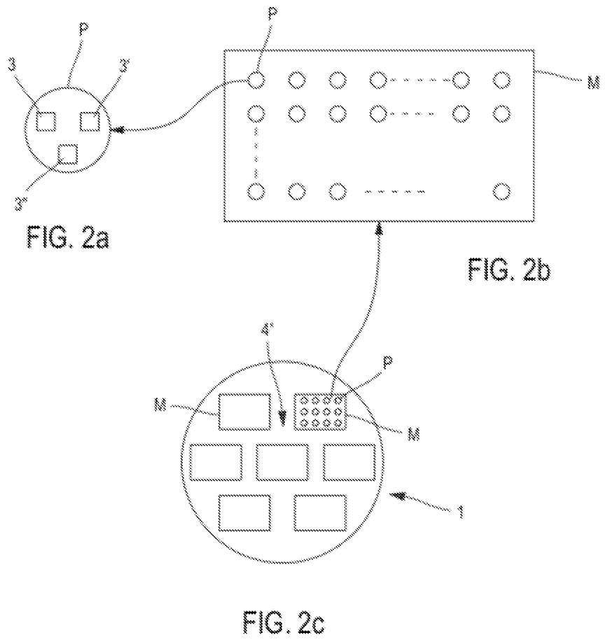

One can advantageously choose to place the islands 3, 3′, 3″ of a first, second, and third group of islands next to each other, which would allow the respective formation of LEDs emitting in different colors, e.g., red, green, and blue, respectively. This arrangement has been represented schematically in FIG. 2a. Such a combination of LEDs constitutes a bright pixel P whose emission color can be controlled. The islands 3, 3′, 3″ that will carry the LEDs constituting these P pixels can be arranged in a regular manner on the surface of the growth medium 2. Monolithic P pixels may thus be formed, i.e., placed on the same substrate and handleable as a pixel, e.g., by a component insertion device, in order to be included in a functional device.

In the case where the formation of a monolithic micro-panel of LEDs is aimed, e.g., for a color micro-display screen, the P pixels could, for example, be distributed evenly according to lines and rows to form a matrix M, as represented in FIG. 2b. A growth substrate 1 may comprise a plurality of such M matrices, as represented in FIG. 2c.

Returning to the description of FIGS. 1a and 1b, and beyond the growth medium 2 and the crystalline semiconductor islands 3, the growth substrate 1 also comprises at least one assembly layer 5 arranged between the growth medium 2 and the islands 3. Herein, the assembly layer is directly in contact with the growth medium and with the islands 3, but the growth substrate could comprise other intermediary layers. This assembly layer 5 may include a dielectric material such as a layer of silicon oxide or silicon nitride, or consist of a stack of such layers designed to, for example, facilitate subsequent removal of the growth medium.

In the variant of the growth substrate 1 shown in FIG. 1b, the assembly layer 5 does not have a uniform thickness. For reasons that will become apparent in connection with the description of the growth substrate 1's manufacturing method; the assembly layer has a first thickness in way of the islands 3 of the first group of islands 3a and a second thickness, which is different from the first, in way of the islands 3 of the second group of islands 3b. In more general terms, the assembly layer 5 has a distinct thickness in way of the islands of each of substrate 1's groups of islands.

### Method for Manufacturing a Growth Substrate

Several examples of manufacturing methods of the growth substrate 1 introduced above are disclosed below.

These methods implement the principles of the crystalline semiconductor island transfer and relaxation technology, such as they are described in documents EP2151852, EP2151856 or FR2936903.

According to an exemplary implementation that complies with this approach, one starts by forming a strained crystalline semiconductor layer on a donor substrate. This layer is then transferred to a substrate comprising a flow layer by bonding and by thinning and/or fracturing the donor substrate. The islands are then defined in the transferred layer, and a heat treatment is subsequently performed on the substrate and the islands at a temperature that is higher than the viscosity transition temperature of the flow layer, e.g., consisting of BPSG, which leads to at least partial relaxation of the islands. The degree of relaxation achieved following the relaxation heat treatment can reach 70 to 80% or 95% of the maximum degree of relaxation corresponding to the achievement of a perfectly relaxed layer. This degree of relaxation depends on the thickness of the islands as well as on the duration and extent of the heat treatment.

To assist this relaxation and prevent an island warpage phenomenon during the plastic deformation that takes place during relaxation, it may be provided that a stiffening layer is formed on or under the islands prior to applying the relaxation heat treatment. As explained in detail in the document entitled “Buckling suppression of SiGe islands on compliant substrates,” Yin et al. (2003), Journal of Applied Physics, 94(10), 6875-6882, the degree of relaxation of an island achieved after this heat treatment step is that which balances the strains in the stiffening layer and in the island. Note that the stiffening layer can be formed from (or include) a residue of the donor substrate that would have been preserved on the strained layer following its transfer to the flow layer. It may have been placed on the exposed face of the donor substrate to end up under the island after the transfer of the strained layer and the formation of the islands.

This disclosure takes advantage of the relaxation phenomenon to provide methods for manufacturing a plurality of crystalline semiconductor islands having a variety of lattice parameters. More specifically, these methods set out to provide a relaxation substrate that comprises a medium 7, a flow layer 8 disposed on the medium 7 and, arranged on the flow layer, a plurality of crystalline semiconductor islands 9 having an initial lattice parameter, at least part of this plurality of islands being strained islands. A first group of islands 9a has a first lateral expansion potential and a second group of islands 9b has a second lateral expansion potential that is different from the first.

“Lateral expansion potential” refers to the lateral expansion or contraction to which an island 9 must be subject to reduce its elastic strain energy and balance it to the energy required to retain the flow layer 8 with which it is in contact.

The methods also provide for heat-treating the relaxation substrate 6 at a relaxation temperature that is higher than or equal to the glass transition temperature of the flow layer 8 to cause differentiated relaxation of the islands of the first and second groups, since the lattice parameter of the first group of relaxed islands 3a and that of the second group of relaxed islands 3b then have different values.

### First Method

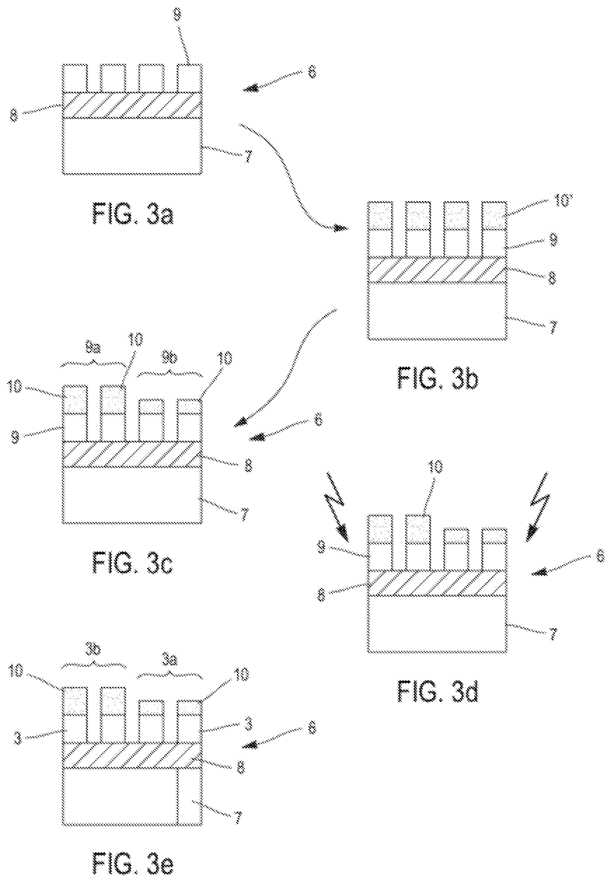

As shown in FIG. 3a, a first manufacturing method according to the disclosure includes the supply of a relaxation substrate comprising a relaxation medium 7, a flow layer 8 disposed on the medium 7 and, arranged on the flow layer 8, a plurality of strained crystalline semiconductor islands 9. The strained islands 9 all have the same lattice parameter. One can refer to the documents mentioned regarding the state of the art to choose the nature of the relaxation medium 7 and of the flow layer 8.

These strained islands 9 may come from a donor substrate and may have been transferred to the flow layer 8 of the relaxation substrate 6 using the bonding and thinning steps briefly mentioned above. As an example, the donor substrate may consist of a sapphire base medium, a GaN buffer layer formed on the base substrate, and an InGaN strained layer with a proportion of indium ranging from 1% or 1.5% to 10% or 20% on the GaN buffer layer. Traditional photolithography, resin depositing, and etching steps may have been used to define the strained InGaN islands 9 from the continuous InGaN layer. These steps may have been applied before or after the transfer steps. As mentioned above, the islands 3 may carry a stiffening layer 10′ that is a residue of the donor substrate. This could be the GaN from 10 to 100 nm thick that initially formed the buffer layer of the donor substrate.

Regardless of the manner in which the relaxation substrate 6 may have been formed, in a subsequent step of the manufacturing method, the strained islands 9 of the relaxation substrate are treated selectively so as to form a first group of strained islands 9a having a first lateral expansion potential and a second group of strained islands 9b having a second lateral expansion potential that is different from the first. In other terms, the strain energy contained in an island of the first group of islands 9a is different from the strain energy contained in an island of the second group of islands 9b.

Such selective treatment may include the formation of a stiffening layer 10 having a first thickness on the first group of strained islands 9a of the relaxation substrate 6 and having a second thickness on the second group of strained islands 9b. This arrangement is represented in FIG. 3c.

This thickness configuration of the stiffening layer 10 may be achieved by forming an initial stiffening layer 10′ of uniform thickness on all islands 9, as shown in FIG. 3b, and then by selectively thinning this layer 10′ to reduce its thickness on one of the two groups of islands 9a, 9b. Again, lithographic photo-masking steps can be used to protect the stiffening layer 10 disposed on one of the island groups against this thinning treatment. As an alternative to thinning, one can also choose to thicken the initial stiffening layer 10′ on one of the two island groups 9a, 9b to end up with the configuration in FIG. 3c. As seen above, this stiffening layer of uniform thickness 10′ can consist of a residue of the donor substrate.

As an alternative or in addition, rather than modifying the thickness of the stiffening layer 10 or one island group in relation to another, one can choose to vary its nature. One can thus have a stiffening layer 10 formed from a first material on a first group of islands 9a and a stiffening layer 10 formed from a second material having a stiffness or rigidity that is different from the first on the second group of islands 9b. In this case, the stiffening layer 10 may have a uniform thickness from one group of strained islands 9a, 9b to another.

For reasons of availability and cost, the stiffening layer 10 is typically composed of a silicon oxide or a silicon nitride. But this may be any other material that is sufficiently rigid to modify the lateral expansion potential of the island 9 on which it rests and potentially prevent the warpage of this island 9 during the relaxation heat treatment that follows. According to the nature of this layer and on the expected degree of relaxation of the island 9 on which it is disposed, the stiffening layer 10 can have a thickness ranging from 10 nm to several hundreds of nm, such as 200 nm.

It may also be provided that certain islands 9 are not coated with a stiffening layer 10. This is particularly the case when the island's degree of strain is relatively low and, thus, when the risk of warpage of this layer only is marginal.

The selective treatment aiming to affect the islands' 9 lateral expansion capacity in a differentiated manner may also include the thinning of certain islands 9, i.e., reducing the thickness of the islands 9a of the first group and/or the thickness of the islands 9b of the second group of islands so that these islands 9a, 9b have different thicknesses following this treatment. This may, for example, include thinning at least one group of islands 9a, 9b, by 10% to 50% of its initial thickness in order to create a difference in thickness between these groups of islands that can be greater than 10%. This variant is particularly useful when the stiffening layer has been formed between the flow layer 8 and the crystalline semiconductor island 9a, 9b, for example, by placing a layer of stiffening material on the donor substrate before transferring the strained layer to the relaxation medium.

In a variant not shown, the stiffening layer is only formed under some of the strained islands 9. The stiffening layer may be formed beforehand on the exposed surface of the donor substrate 11 and locally etched so as to selectively form islands with or without this underlying layer or with a variable thickness of this stiffening layer. The islands 9 that have an underlying stiffening layer will have a lower lateral expansion potential than the islands without stiffening layer, for an identical flow layer.

All the selective treatments that have just been described may be combined with one another. In all cases, following this treatment aiming to form at least two groups of islands 9a, 9b, there is a first group of islands 9a having at least one characteristic (thickness, thickness or nature of a carried stiffening layer) that differs from the characteristic of a second group of islands 9b. Consequently, they have a differing lateral expansion potential or capacity.

In a subsequent step of the manufacturing method, shown in FIG. 3d, the relaxation substrate 6 is heat-treated at a temperature that is higher or equal to the glass transition temperature of the flow layer 8. According to the nature of this layer, this heat treatment may include exposing the relaxation substrate to a temperature comprised between 400° C. and 900° C. for a period ranging from a few minutes to several hours. This is particularly the case when the flow layer consists of BPSG. Proceeding in this way causes the relaxation of the strained islands 9 of the first and second groups of islands 9a, 9b to form at least partially relaxed islands 3, shown in FIG. 3e. As has been well documented, the degree of relaxation achieved during and following the relaxation heat treatment depends on the thickness of the island 9, the thickness and/or on the nature of the stiffening layer 10 that may possibly cover this island 9.

The strained islands of the first group 9a and the strained islands of the second group 9b have different characteristics and, thus, a different lateral expansion potential, the heat treatment leads to relaxing, to varying degrees, the initially strained islands 9 of the first and second group 9a, 9b. In other terms, following the relaxation heat treatment, the lattice parameter of the islands 3 of the first group of islands 3a is different from the lattice parameter of the islands 3 of the second group of islands 3b.

### Second Method

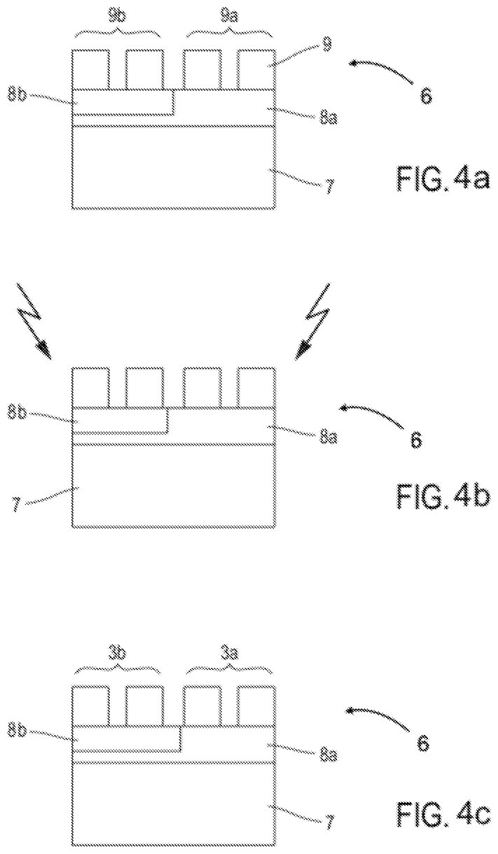

This second method of manufacturing islands 3 having a variety of lattice parameters is now described with reference to FIGS. 4a to 4c. As for the first method, a relaxation substrate 6, comprising a relaxation medium 7, a flow layer 8 disposed on the medium 7 and, arranged on the flow layer 8, a plurality of strained crystalline semiconductor islands 9, is supplied. The strained islands 9 all initially have the same lattice parameter.

In this second method and with reference to FIG. 4a, the flow layer 8 consists of a first group of blocks 8a and of a second group of blocks 8b. Herein, each group 8a, 8b consists of a single block for the sake of simplifying the description, but in general terms, a group of blocks may consist of one or of a plurality of blocks. The term “block” must be understood in a very broad sense, referring to a block or combination of blocks of homogeneous material, where this block defines any volume, which is not necessarily convex.

The blocks of the first group 8a and the blocks of the second group 8b are composed of different materials, which, for a given temperature, respectively have a first and second viscosity that are different one from another. The strained islands 9 arranged on the blocks 8a of the first group form a first group of strained islands 9a and, similarly, the strained islands 9 arranged on the blocks 8b of the second group form a second group of strained islands 9b.

The viscosity of the blocks 8a of the first group being different from the viscosity of the blocks 8b of the second group, the strained islands 9 are likely to relax, at least partially, in a differentiated manner. In other terms, the strained islands of the first group 9a have a relaxation potential that is different from the relaxation potential of the strained islands 9b of the second group. Insofar as the strained islands 9 are all of the same dimensions, the strain energy they contain is generally similar, but the nature of the block on which they rest being different, the islands 9 are likely to relax in a differentiated manner.

The strained islands 9 may come from a donor substrate 11 and may have been transferred to the flow layer 8 of the relaxation substrate 6 using identical or similar steps as those mentioned in connection with the description of the first method.

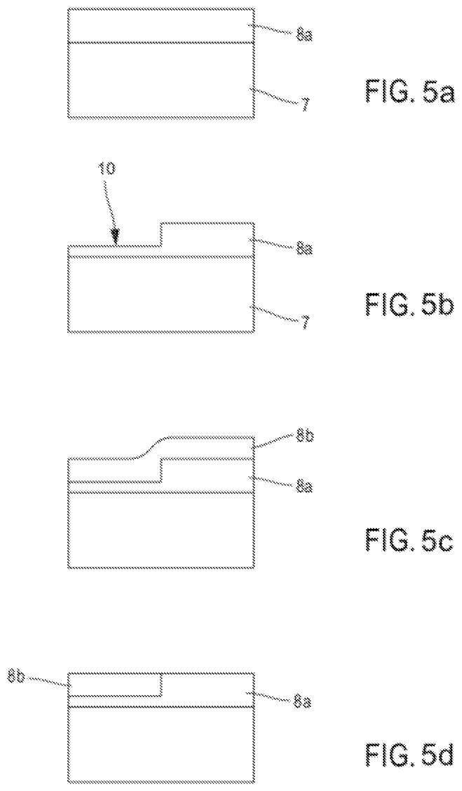

FIGS. 5a to 5d show a sequence of possible steps to produce a flow layer 8 consisting of blocks 8a, 8b of different viscosities. With reference to FIG. 5a, a first flow layer 8a is formed on the medium 7. This may be a dielectric layer of silicon dioxide or of silicon nitride comprising a determined proportion of boron and/or of phosphorous in order to give it a first viscosity value. In the following step, shown in FIG. 5b, at least one recess 10 is provided through partial masking and etching of the first flow layer 8a. The recess 10 may be partial, as shown in the figure, or correspond to the entire thickness of the first flow layer 8a. In a subsequent step, the remaining first layer 8a and the recess 10 of a second flow layer 8b are coated. This second layer 8b preferably has a sufficient thickness to fill the entire recess 10. The material making up the second flow layer 8b is of a different nature than that of the first layer 8a so that the first and second layers have a different viscosity when they are exposed to a determined relaxation temperature.

This different viscosity may either be higher or lower than that of the first layer 8a. For example, if the first layer is made of silicon dioxide or silicon nitride, which has a particularly high viscosity, the material chosen for the second layer 8b may be BPSG, with a sufficient boron and phosphorous mass proportion, for example, higher than 4%, to have a lower viscosity than that of the first layer.

With reference to FIG. 5d, the exposed surface of the substrate is then planarized to eliminate the second flow layer except for in the recesses 10 until the first flow layer 8a is exposed. The first blocks 8a and the second blocks 8b making up the flow layer 8 are thus formed. It should be noted that the flow layer 8 thus produced has a particularly plane surface, which makes it favorable for receiving the strained islands 9 by means of a layer transfer.

Returning to the second manufacturing method and in a subsequent step of this method shown in FIG. 4b, the relaxation substrate 6 is heat-treated at a relaxation temperature that is higher than or equal to the glass transition temperature of the flow layer, i.e., of at least one of the first and second blocks 8a, 8b of the flow layer 8 to cause the differentiated relaxation of the islands 9a, 9b of the first and second groups. According to the nature of the blocks making up this layer, the heat treatment may include exposing the relaxation substrate 6 to a relaxation temperature between 400° C. and 900° C. for a period ranging from a few minutes to several hours. Proceeding in this way causes the lateral expansion of the strained islands 9 of the first and second groups of islands 9a, 9b to form at least partially relaxed islands 3, shown in FIG. 4c.

In other terms, since the strained islands of the first group 9a and the strained islands of the second group 9b rest on blocks having different viscosities at the relaxation heat treatment temperature and, thus, having a different lateral expansion potential, the heat treatment leads to relaxing, to varying degrees, the initially strained islands 9 of the first and second group 9a, 9b and to causing their differentiated lateral expansion. Therefore, following the relaxation heat treatment, the lattice parameter of the islands 3 of the first group 3a is different from the lattice parameter of the islands 3 of the second group 3b.

### Third Method

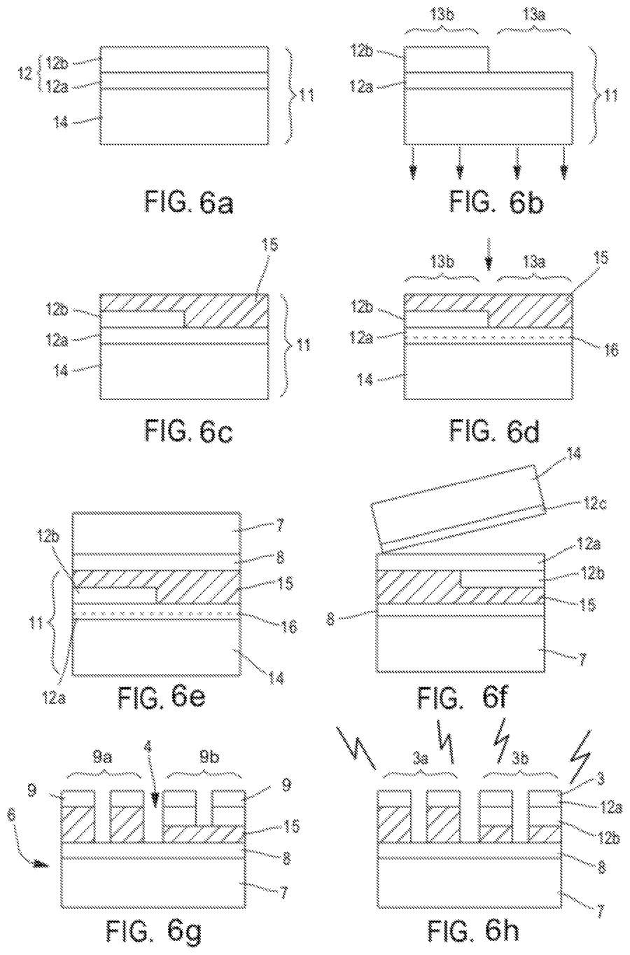

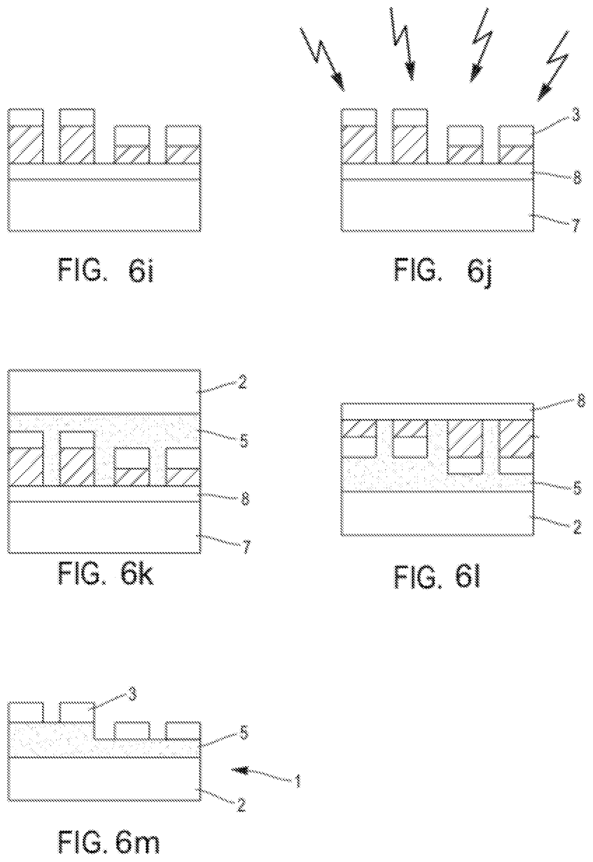

A third method for providing relaxed islands 3 having a variety of lattice parameters is presented with reference to FIGS. 6a to 6m. This third method includes the preparation of a donor substrate 11 comprising a plurality of strained elementary layers of crystalline semiconductors 12a, 12b forming a stack 12. The stack has at least one first area 13a and one second area 13b that have different strain levels.

FIG. 6a shows the first step in preparing the donor substrate 11. It includes the supply of a base substrate 14, for example, consisting of sapphire, silicon or silicon carbide. A stack 12 of semiconductor and crystalline elementary layers is formed on the base substrate 14, each layer in the stack having a different nature. In the example shown in FIG. 3a, two crystalline semiconductor elementary layers 12a, 12b are formed. By way of illustration, the first elementary layer 12a can be a layer of gallium nitride having a thickness of 2 microns or more, forming a buffer layer and whose upper part is essentially relaxed. The second elementary layer 12b can be a layer of InGaN of a thickness of about 100 nm and whose proportion of indium is of about 6%. The second elementary layer 12b in the stack 12, and in general terms each elementary layer in the stack 12, has a thickness that is less than its critical relaxation thickness. At least some of the layers are thus strained, in compression in the example chosen above. In this way, the second elementary layer 12b (or each layer in the stack 12 formed on top of the first elementary layer 12a) is pseudomorphous and, thus, has a lattice parameter that is identical to the one of the first layer 12a in the stack 12.

A subsequent step in the preparation of the donor substrate 11 is shown in FIG. 6b, which consists in locally eliminating the second elementary layer 12b to expose part of the first elementary layer 12a. This elimination step may involve traditional means of photolithographic masking and etching, e.g., dry etching. Proceeding in this way defines, on the exposed surface of the donor substrate 11, a first area 13a, in which the first layer 12a is exposed, and a second area 13b in which the second layer 12b of the stack is exposed. Generally speaking, during this step, part of the stack 12 is eliminated locally so as to preserve in respective areas 13 only part of the layers that form the stack 12. The areas 13 have strain levels that are different one from another, since each area 13 is respectively formed by a different stack of one or of a plurality of elementary layers, each in a different state of strain.

Thus, in the example shown in FIG. 6b, the area 13a consists of the first layer 12a and has a first reference strain level. The area 13b consists of the stack formed of the first elementary layer 12a and of the strained second elementary layer 12b. The second area 13b, therefore, has a higher strain level than the first area 13a.

The areas 13a, 13b are not necessarily all in one piece, i.e., locally eliminating elementary layers of the stack 12 to expose a specific layer can be carried out in a plurality of distinct and non-contiguous locations. The term “area” will be used to designate the collection of locations on the surface of the donor substrate 11 having the same strain level, e.g., for which the same layer 12a, 12b of the stack 12 is exposed following the elimination step.

The first and second areas 13a, 13b of the donor substrate will each respectively allow creating the islands 3 of the first and second groups of relaxed islands 3a, 3b of a growth substrate 1. It will be sought to define these areas on the surface of the donor substrate 11 in such a way that they correspond to the chosen arrangement of the islands 3 of the groups 3a, 3b, as this has been disclosed above in connection with FIGS. 2a to 2c.

The following donor substrate 11 preparation steps shown in the FIGS. 6c and 6d are aimed at preparing the transfer of the stack 12 thus defined to a relaxation medium 7.

The formation of a bonding layer 15 having a plane and smooth exposed surface is thus provided to enable the assembly of the donor substrate 11 on the medium 7. This can be a dielectric layer, e.g., made of silicon dioxide or silicon nitride. When silicon dioxide is used, it may include boron and/or phosphorous to provide it with flowing properties when the bonding layer 15 is exposed to a temperature that is higher than its glass transition temperature. This bonding layer 15 is deposited with a sufficient thickness to be able to encapsulate the entire stack 12 and, thus, provide a plane surface. When its formation provides for applying a polishing step, the removal of thickness that occurs during this processing must be taken into account. For example, a thickness of 500 nm or more of material can be deposited to form the bonding layer 15.

In an optional step shown in FIG. 6d, light species, such as hydrogen or helium, are introduced in the donor substrate 11. The introduction of these species leads to forming a brittle plane 16 that allows for the base substrate 14 to be eliminated in a subsequent step of the manufacturing method and to transfer the stack 12 to the relaxation medium 7. The brittle plane 16 may preferably be located in the base medium 14 or in the first elementary layer 12a of the stack 12 so that the stack 12 may indeed be transferred to the medium 7.

It should be noted that the embrittlement plane 16 may sometimes not be perfectly plane when the introduction of the light species is carried out by implanting ions throughout the bonding layer 15 and throughout the elementary layers of the stack 12. This has no consequence on the application of the manufacturing method, in as far as this plane remains well localized within the stack 12. It may also be provided that the order of the steps for forming the bonding layer 15 and for forming the brittle plane 16 are reversed to prevent this phenomenon. It may also be provided that the brittle plane 16 is formed before the areas 13 having different strain levels are defined. In both these cases, it will be ensured that, during the formation of the bonding layer 15, the donor substrate 11 is not exposed to an excessive thermal budget, which would cause the deformation of the stack by a bubbling effect of the implanted species.

FIGS. 6e and 6f respectively show the assembly of the donor substrate 11 with the relaxation medium 7, and the removal of the base medium 14 and of a residue 12c of the first elementary layer 12a. The removal is performed after a fracture of the assembly at the embrittlement plane 16, in this case arranged in the first elementary layer 12a. This removal step may include the exposure of the assembly to a moderate temperature of a few hundred degrees and/or the application of strains, e.g., of mechanical origin.

However, this third manufacturing method is in no way limited to a transfer involving the formation of an embrittlement plane 16. It is feasible to perform the transfer to the medium 7 by mechanical/chemical removal of the base medium 14, in particular when it consists of silicon. It is also feasible to detach it by laser irradiating the interface separating the base substrate 14 and the first elementary layer 12a, in particular, when the base substrate consists of sapphire.

The relaxation medium 7 has been previously provided with a flow layer 8 so that, after the operation consisting in the removal of the base medium 14, a relaxation substrate 6 is obtained, which comprises the relaxation medium 7, the flow layer 8, the bonding layer 15 and the stack 12 of crystalline semiconductor elementary layers defining areas 13 having different strain levels.

In the following step, shown in FIG. 6g, trenches 4 are made in the stack 12 so as to define strained islands 9. The trenches 14 are made in the stack 12 to define the islands 9 of a first group of islands 9a in the first area 13a and to define the islands 9 of a second group of islands 9b in the second area 13b. These trenches 4 may enter into the bonding layer 15, if not into the flow layer 8. This step of defining the islands 9 can be carried out after the transfer of at least part of the stack 12 as shown here, but it is also feasible to carry out this step before the transfer of the stack 12, directly onto the donor substrate 11. As seen, the formation of trenches 4 may lead to the definition of islands 9 of very varied shapes and dimensions.

In any event, following these steps a relaxation substrate 6 is obtained, which comprises a medium 7, a flow layer 8 arranged on the medium and a bonding layer 15 arranged on the flow layer 8. As seen, the flow layer 8 and the bonding layer 15 may both consist of BPSG and, thus, have flowing properties. The relaxation substrate 6 also includes, on the flow layer 8, a plurality of crystalline semiconductor islands all having the same initial lattice parameter. A first group of islands 9a has a first strain level. These are the islands 9 that have been formed in the stack 12 at the level of the first area 13a of this stack. A second group of islands 9b has a second strain level that is different from the first. These islands 9 of the second group 9b are the ones that have been formed in the stack 12 at the level of the second area 13b of this stack.

In more general terms, the relaxation substrate 6 may comprise a plurality of groups of islands that have different strain levels from one to the next, each group of islands having been formed in the stack 12 at the level of a well-defined area 13 of this stack 12. The strained islands 9 of each group of islands have a different lateral expansion potential from one group to the next. The strain energy contained in an island 9 of the first group 9a thus is different from the strain energy contained in an island 9 of the second group 9b.

To release this strain energy and cause the differentiated lateral expansion of the islands 9 of the first group 9a and of the islands 9 of the second group 9b, and similarly to the first and second methods disclosed, the heat treatment of the relaxation substrate 6 is provided for. As for the other methods, this may, for example, be a heat treatment bringing the substrate 6 to a temperature of 800° C. for a period of four hours. In more general terms, the relaxation temperature chosen for this heat treatment will be such that it exceeds the glass transition temperature of the flow layer 8 and possibly that of the bonding layer 15 when it has flowing properties. This relaxation temperature typically ranges from 400° C. to 900° C. The heat treatment may last between 30 minutes and several hours.

Of course, if a group of islands 9 is not in a strained state, as is the case of the islands 9 consisting of the first layer 12a made of gallium nitride in the previous example, the lattice parameter of these islands is not affected by the relaxation heat treatment.

In any event, since the islands forming the various groups of islands 9a, 9b initially have different strain levels, the application of the relaxation heat treatment leads to the relaxation and to a lateral expansion of the islands that is differentiated from one group to the next. The relaxed islands 3 of the first group 3a and the islands 3 of the second group 3b then have different lattice parameters.

Two relaxation heat treatments leading to the relaxation of the strained islands 9 in different manners are thus shown in FIGS. 6h and 6j for the sake of illustration. As shown in FIG. 6i, a step in which the thickness of the partially relaxed islands 3 of the second group of islands 3b is reduced has been carried out between these two steps. In the example shown, reducing the thickness has led to eliminating from these islands 3 the part of the thickness corresponding to the original layer 12a so as to expose the original layer 12b. But this choice is in no way restrictive and part of the original layer 12a of the islands of the second group 3b could have been preserved or all of the islands 3 of each group of islands 3a, 3b could have been thinned.

Following this third manufacturing method described above, one can choose to proceed with the transfer of the at least partly relaxed islands 3 to another medium. With reference to FIGS. 6k to 6m, the islands 3 may, for example, be transferred to a growth medium 2 by means of an assembly layer 5. To this end, the islands 3 are coated with the assembly layer 5, this layer is assembled to the growth medium 2 (FIG. 6k), the assembly layer may have undergone treatments to facilitate this, and the relaxation medium 7 is eliminated by any appropriate means to obtain the structure in FIG. 6l. The flow layer 8 and the bonding layer 15 are then eliminated from the structure obtained. Additional etching steps may help to eliminate any excess of the assembly layer 5 so as to then obtain a growth substrate 1 (FIG. 6m) such as previously described in connection with FIG. 1b.

Regardless of the method used to provide the relaxed islands, the degree of relaxation obtained during and following the relaxation heat treatment depends among others on the dimensions of an island 9, on its strain level, and on the nature of the flow layer 8 on which it rests and, more specifically, on the viscosity of the material that this layer (or this block in the case of the second method) consists of.

And regardless of the method used, it may also be provided that the thickness of the islands is modified or that a possible stiffening layer of the islands of the first group and/or of the second group of islands 3a, 3b, or of any other group of islands, is thinned/thickened prior to applying an additional relaxation heat treatment step. In this way, the lattice parameters of the islands 3 arranged on the relaxation substrate 6 may be refined by repeating the application of a relaxation heat treatment. As has already been mentioned, forming more than two groups of islands 3a, 3b may of course be considered.

In the case of the first method, a preliminary relaxation heat treatment step may be provided prior to selectively treating the islands 9 in view of differentiating them. In this case, all the islands 9 are relaxed to the same degree of relaxation. In each of the three methods disclosed, it may also be provided that the thickness of the islands is modified or that the stiffening layer 10 of the first group and/or of the second group of islands 3a, 3b, or of any other group of islands, is thinned/thickened prior to applying an additional relaxation heat treatment step. In this way, the lattice parameters of the islands 3 arranged on the relaxation substrate 6 may be refined by repeating a cycle of selective treatment of the islands and of application of a relaxation heat treatment. As has already been mentioned, forming more than two groups of islands 3a, 3b may, of course, be considered.

In more general terms and regardless of the method used, any step aiming to modify a characteristic of a group of islands 9a, 9b affecting its lateral expansion potential may be combined, so that each island has a lattice parameter that is close or identical to a target lattice parameter following the relaxation heat treatment.

Following any of the manufacturing methods described above, one can choose to proceed with the transfer of the relaxed islands 3 to another medium, as has been illustrated for the third method. This transfer may include carrying these islands over to an intermediary medium prior to transferring them to this other medium. For example, one can choose to transfer the islands 3 to a growth medium 2, possibly via an assembly layer 5, which would then allow having a growth substrate 1 such as has been described above and shown in FIG. 1a (for the first and second methods) and in FIG. 1b (for the third method). A growth substrate that does not contain any flow layer is thus obtained, since the flow layer may be incompatible with the steps required to manufacture the active layers of the optoelectronic devices. Moreover, in the case where these islands are composed of a polar material, this transfer allows retrieving the initial polarity of this material, such as it had been formed on the donor substrate, from the exposed face of the growth medium 1.

### Method for Manufacturing a Plurality of Optoelectronic Devices

According to another aspect, the disclosure also relates to a method for the collective manufacture of a plurality of optoelectronic devices. According to the disclosure, these devices each comprise active layers that may be different from one device to another. The devices then have optoelectronic properties that differ from each other. The terms “collective manufacturing” are used to mean that the manufacture of these devices uses a single technology applied to a single substrate to form the active layers.

This method includes supplying a growth substrate 1 in line with the general description provided above. It, therefore, at least comprises a first group of crystalline semiconductor islands 3a having a first lattice parameter and a second group of crystalline semiconductor islands 3b having a second lattice parameter that is different from the first.

The following step is aimed at forming the active layers by growth on the exposed face of these islands 3. As is well-known as such, to achieve this, the growth substrate is placed in a deposition chamber, e.g., that of an epitaxy frame. During deposition, streams of precursor gases flow through such a chamber, these gases comprising the atomic elements that compose the active layers to be deposited on the islands 3. The precursor gases are heated to temperature above the growth substrate 1 so as to free the atomic elements and to enable their adsorption on the surface of the growth substrate 1 and, in particular, on the surface of the islands 3. According to the nature, the relative concentration, and the period during which these precursor gases circulate, the nature and the thickness of these layers, which are progressively formed on the crystalline semiconductor islands 3, can be controlled. If this is necessary, it may be provided that type p or n doping agents are introduced in the chamber to elaborate doped layers. In particular, the precursor gases can be controlled to form active layers of electronic devices, such as quantum wells or LED heterostructures, on the islands.

By way of example, an active layer of LEDs may include the stack with the following layers on an island 3 composed of InGaN having an In concentration less than 20% and at least partially relaxed (typically to the order of 70% or 90%):
an n-doped InGaN layer having an In concentration similar to that of the island 3;
a multiple quantum well comprising a plurality of layers, each layer including a distinct proportion of indium, having a difference of a few percentage points in relation to that of the underlying n-doped layer. The quantum well is capable of emitting a light radiation of a wavelength selected according to the nature of the layers that it consists of;
a p-doped InGaN layer having an In concentration ranging from 0 to 10%. To simplify its manufacturing, it can also be provided that the p-doped layer be formed from GaN.

The precursor gases used to form these active layers of LEDs can include trimethylgallium (TMGa), triethylgallium (TEGa), trimethylindium (TMIn), and ammonia (NH3).

The incorporation of certain atomic elements of the precursor gases in the deposited layer is affected by the lattice parameter of this layer. This is particularly the case for what concerns the incorporation of indium in an InGaN layer, as has been reported in the document entitled “Strain effects on indium incorporation and optical transitions in green-light InGaN heterostructures of different orientations,” by M. V. Durnev et al., Phys. Status Solidi A 208, No. 11, 2671-2675 (2011). It appears that the solubility of indium in a material increases as the lattice parameter of this material increases. In other terms, all other things being equal, the incorporation of indium in a material during its formation by deposition increases with the lattice parameter of the material into which it is incorporated.

The present disclosure takes advantage of this observation to form the growth substrate 1 of the active layers of a plurality of optoelectronic devices, these active layers may be different from one device to another. The method generally implements a step in which the growth substrate 1 is exposed to an atmosphere comprising at least one initial concentration of an atomic element.

On the islands 3 of the first group 3a of the growth substrate 1, which has a first lattice parameter, the atomic element is incorporated in the active layer in a first concentration. On the islands 3 of the second group of islands 3b, which has a second lattice parameter that is different from the first, the atomic element is incorporated in the active layer according to a second concentration that is different from the first. If the second lattice parameter is greater than the first, the second concentration will be greater than the first.

In other terms, the first and second concentrations are determined by the initial concentration of the atomic species in the chamber and by the first and the second lattice parameters of the islands. As is well-known in the field of material growth, other parameters may also influence the nature of the layers that are formed, such as, for example, the pressure of the chamber, the temperature, and the respective flow of the precursor gases, etc.

By providing a growth substrate for which the first and the second lattice parameter have been adequately selected, it is possible to form active layers having different optoelectronic properties. By way of example, the proportion of indium incorporated in the InGaN active layers deposited on the islands of the first group of islands may lead to the formation of LEDs directly emitting a radiation within the blue range. At the same time, the proportion of indium incorporated in the InGaN active layers deposited on the islands of the second group of islands can lead to the formation of LEDs directly emitting a radiation within the green range.

Once the active layers have been formed on the islands, one can proceed with the method of manufacturing electronic devices, in particular, to form the electrical contacts and to isolate the devices one from another, as is described in document U.S. Pat. No. 9,478,707, for example. It may also be provided that the islands 3 coated with their active layers are carried over to an LED support and that the growth medium 2 is eliminated.

### Application to the Manufacturing of a Monolithic Micro-Panel of LEDs and to a Micro-Display Screen

A specific application of the growth substrate and of the collective manufacturing method described above aims to manufacture a monolithic micro-panel of LEDs.

Such a micro-panel consists in an arrangement of LEDs, generally all identical and of very small size, arranged into rows and columns at a constant pitch on a panel support. When the LEDs have been manufactured collectively, the micro-panel is said to be “monolithic.” This characteristic is advantageous, since the LEDs then have very similar properties (such as the current and/or voltage behavior, changes with ageing, etc.), which facilitates the design and the manufacturing of the micro-panel. Within the scope of the present disclosure, a micro-panel in which all the LEDs have been manufactured collectively and extracted collectively from the same manufacturing medium to form the micro-panel will be designated by monolithic micro-panel; or a micro-panel consisting of monolithic pixels, i.e., each pixel consists of LEDs manufactured collectively and extracted collectively from the same manufacturing medium. In this case, the monolithic pixels are assembled together so as to form the micro-panel.

The monolithic micro-panel of LEDs can be assembled with a pilot circuit using a “flip-chip” technology, which allows performing the electrical connection of each LED of the micro-panel with a driving circuit of the pilot circuit. This assembly may consist in assembling an entire monolithic micro-panel with a pilot circuit, each LED of the micro-panel being associated with a driving circuit after assembly. Or the assembly may consist in successively assembling one or a plurality of monolithic pixels to the pilot circuit to associate them with the pilot circuit. Regardless of the chosen approach, a monolithic micro-display screen is formed when proceeding in this way.

Since the LEDs all have identical or similar electrical properties, the driving circuits of the pilot circuit may also have identical or similar electrical properties, which considerably facilitates the manufacturing of the micro-display screen.

A detailed discussion of this device and its manufacturing method can be found in “Monolithic LED Microdisplay on Active Matrix Substrate Using Flip-Chip Technology,” Liu et al., IEEE Journal of Selected Topics in Quantum Electronics (Volume: 15, Issue: 4, July-August 2009)

Note that known monolithic micro-panels all consist of LEDs directly emitting a single wavelength thus enabling monochrome display. Color display is achieved via the phosphorus conversion placed on the emitting face of some of these LEDs, or by optically combining a plurality of micro-panels each emitting a radiation chosen in a combination of complementary colors, e.g., red, green and blue. These techniques are not advantageous for obvious reasons of complexity of implementation, of efficiency, and of density, as has been recalled in the introduction to the present application.

On the contrary, the methods and substrates according to the present disclosure can be used to provide a monolithic micro-panel of LEDs comprising a panel support and a plurality of LEDs arranged on this panel. The plurality of LEDs includes a first group of LEDs capable of directly emitting a light radiation having a first wavelength and a second group of LEDs capable of directly emitting a second light radiation having a second wavelength that is different from the first.

A micro-panel according to the disclosure is thus capable of emitting different colors without needing to optically combine a plurality of micro-panels or to apply conversion means. For applications in the field of color displays, the micro-panel comprises at least three groups of LEDs, each group emitting a wavelength that is different from that of the others. There can, for example, be a first group of LEDs directly emitting in the red, a second group of LEDs directly emitting a radiation in the green, and a third group of LEDs directly emitting a radiation in the blue. Having a fourth group of LEDs directly emitting in the infrared can also be considered, this illumination being used to provide additional features to the device in which the micro-panel is integrated (tactile function, eye iris recognition, motion sensing, etc.).

For applications in the field of color displays, the LEDs of each group are arranged evenly on the panel support, e.g., spaced at a constant pitch along rows and columns in order to form a display matrix. They are also arranged to place side by side, or more precisely in close proximity to each other, an LED of each group so as to form a bright pixel, whose color can be controlled, in each location of the matrix. The size of the LEDs may vary according to the group in order to play on the distribution of the luminous intensities of the various emission colors. For example, red LEDs may be larger than blue and green LEDs.

The micro-panel may consist of LEDs that can be used to form a matrix of large-sized pixels, e.g., of 50 pixels by 50 pixels, or of 200 pixels by 200 pixels, if not more.

Even though the bright pixels of the panel consist of LEDs emitting in different wavelengths, these LEDs have been formed collectively using a single technology and on a single substrate. They thus have properties, and more specifically electrical and ageing properties, that are very similar with each other, which allows associating them with a pilot circuit consisting of driving circuits that are all identical or very similar.

Several examples of how to prepare a micro-panel and/or micro-display screen implementing one of the three methods for manufacturing islands having a variety of lattice parameters that have been explained in detail will now be disclosed.

### First Example

In this first example, a growth substrate 1 comprising a growth medium 2 provided with a silicon oxide assembly layer 3 is first prepared. The growth medium may, for example, consist of a silicon wafer 150 mm in diameter. The growth substrate is composed of three groups of InGaN islands 3a, 3b, 3c containing 8% of indium. The islands 3a, 3b, 3c all have a thickness of 200 nm and a square shape of 50 microns on a side. The first group of islands 3a has a lattice parameter of 0.3190 nanometers, the second group has a lattice parameter of 0.3200 nanometers, and the third group has a lattice parameter of 0.3205 nm. These target lattice parameters have been chosen so that the collective manufacturing step of the active layers of LEDs leads to the formation of LEDs emitting radiations in the blue, green, and red or close to these.

The islands 3 that make up each of these groups are distributed and arranged on the growth medium 2 according to a matrix arrangement in line with what has been disclosed in relation with the description of FIGS. 2a to 2c. Three islands 3, 3′, and 3″ of each of the groups are thus arranged in close proximity to each other so as to define a pixel; and these groupings of islands distributed according to a matrix along the rows and lines on the surface of the growth substrate 1. Panel trenches 4′ that are larger than the trenches 4 separating the two islands may be provided to separate the matrices one from another, each matrix delimiting a set of islands 3, 3′, 3″ intended to carry the LEDs of a micro-panel.

To manufacture this growth substrate 1, a relaxation substrate 6 comprising a relaxation medium 7, e.g., made of sapphire also 150 mm, and a flow layer consisting of BPSG are first prepared. The relaxation substrate also comprises strained InGaN islands 9 containing 8% of indium. These strained islands 9 are arranged in a similar manner as what has been described above for the relaxed islands 3 of the growth substrate 1. Likewise, the parameter of these strained islands 9 is of 0.3185 nanometers.

The strained islands 9 are coated with an initial GaN stiffening layer 10′ 50 nm thick, a residue of a GaN buffer layer of a donor substrate used to realize the relaxation substrate. A relaxation heat treatment is performed, for example, at 800° C. for one hour. This treatment leads to the relaxation of the initially strained islands 9 to form partially relaxed islands 3 that have a lattice parameter close to 0.3190 nanometers following the relaxation heat treatment. If this is not the case, the relaxation heat treatment can be applied again, possibly by thinning the initial stiffening layer to promote the relaxation of the islands 3.

Only the stiffening layer 10′ that covers the islands 3 of the second and third groups is then eliminated through etching, and then the relaxation heat treatment is renewed. It may also be provided that the islands 3 of the second and third groups are thinned, e.g., by 40 nm, to promote their relaxation. Following the treatment, the lattice parameter of the islands of the first group, coated with the stiffening layer 10, has not changed much, close to 0.3190 nm. However, the lattice parameter of the islands of the second and third groups has increased to come close to 0.3200 nm.

In a subsequent step, only the islands of the third group are thinned, e.g., by 70 nm, and the relaxation heat treatment is applied again. The lattice parameters of the islands of the first and second groups remain relatively constant and are in any case less affected by this heat treatment than the lattice parameter of the islands of the third group, which is then close to 0.3205 nm.

This final relaxation heat treatment can be renewed, possibly in combination with a thinning of the stiffening layer disposed on the islands of the first group or a thinning of the islands of the second and third groups to make the lattice parameters of these islands converge towards their target lattice parameters.

In any event, repeating these steps leads to the selective relaxation of the island groups and, following these steps, the first group of islands 3a has a lattice parameter of, or close to, 0.3190 nanometers, the second group has a lattice parameter of, or close to, 3.200 nanometers, and the third group has a lattice parameter of, or close to, 3.205 nm.

The partially relaxed InGaN islands 3 are then carried over by bonding on a growth medium 2 provided with an assembly layer 5, e.g., a multilayer of silicon dioxide and nitride.

It is then placed in a chamber of an epitaxy frame, in which a set of precursor gases (TMGa, TEGa, TMIn, and NH3) is circulated in order to make active layers of nitride-based LEDs grow on each of the islands.

The lattice parameters of the islands of the first group, of the second group, and of the third group of islands being different from each other, the incorporation of indium in the active layers of InGaN that form on the islands of these groups also is different. On the islands of the first group, LEDs directly emitting radiation in the blue range are obtained, on the islands of the second group LEDs directly emitting radiation in the green range, and on the islands of the third group LEDs directly emitting radiation in the red range are formed.

Following this deposition step, on the growth substrate 1, there thus are active layers of LEDs arranged at the level of a pixel and emitting colors in the red, green, and blue ranges.

The manufacturing of a functional LED on the growth substrate can be completed, among others, by forming the LED contacts on either side of the active layers.

If at this stage, monolithic micro-panels are desired, the wafer on which the LEDs that have just been formed rest can be cut along the trenches 4′ defining the pixel matrices. Each of these matrices then constitutes a micro-panel.

Alternatively, the wafer comprising the micro-panels may also be assembled with a second wafer on which pilot circuits, consisting of a matrix of driving circuits, have been formed. Each matrix is arranged on the surface of this wager according to the same arrangement as the LEDs on the growth substrate. The assembly enables contacting electrically each diode with a driving circuit. A plurality of display screens is constituted in a single contacting step. It can then be decided that the growth medium 2 be eliminated, e.g., by laser irradiation, and the assembly layer 5, e.g., by chemical etching, so as to expose a light emission surface of the LEDs. These surfaces can be prepared using optical surface treatment or protection elements in order to improve the quality and the robustness of the screen. The wafer can be cut out in a conventional manner so as to isolate the screens from each other in view of packaging them.

### Second Example

A donor substrate 11 composed of a sapphire substrate 150 nm in diameter and of a stack of elementary layers having the following characteristics is prepared:
a first layer of buffer gallium nitride 2 microns thick and whose upper part is essentially relaxed;
a second strained InGaN elementary layer containing 8% of indium and 200 nm thick;
a third strained InGaN elementary layer having an indium content of 16% and 40 nm thick.

An intermediate layer of AlGaN, containing between 0% and 10% of aluminium and of a thickness ranging from 1 to 3 nm, may be provided between the second and third layers. This intermediate layer allows ensuring that the stack 12, particularly the third elementary layer, actually is pseudomorphous, i.e., all elementary layers all have the same lattice parameter. The concentration of indium increases from one layer to the next. The strain level of each layer is also increasing.

The first, the second, and the third elementary layers are exposed at the level of three areas of the donor substrate through localized etching, which can be performed in a conventional manner by photolithographic masking and dry etching. Each area is respectively distributed to the surface of the donor substrate 11 according to the pixel and matrix distribution introduced in connection with FIGS. 2a to 2c.

After defining the areas, a 500 nm thick bonding layer 15 containing silicon dioxide and boron as well as a 4% mass proportion of phosphorous is prepared. The bonding layer is polished to enable its assembly to a sapphire growth medium 7. The stack 12 of elementary layers is then transferred to a sapphire relaxation medium 7 that is also 150 nm in diameter, e.g., according to the fracture implantation technique explained in detail in the general description of the method. The sapphire substrate 7 has been previously provided with a BPSG flow layer 8, i.e., containing silicon dioxide as well as boron and phosphorous, in this case with a 4% mass proportion of phosphorous and 6% of boron.

After the stack 12 has been transferred to the flow layer 8 of the sapphire relaxation substrate 7, three groups of strained islands 9 are delimited by making trenches 4, the islands 9a of the first group of islands are defined in the first area 13a, the islands 9b of the second group are defined in the second area and islands of the third group are defined in a third area of the stack. In this case, the islands 9a, 9b are all 10 microns square. The islands 9 of the first group consist of a single layer of GaN, the first elementary layer which is essentially relaxed. The islands 9 of the second group consist of a stack composed of one layer of GaN and one layer of InGaN containing 6% of indium, the second elementary layer is strained. The islands of the third group consist of a stack composed of one layer of GaN, one layer of InGaN containing 8% of indium (the second elementary layer) and a layer of InGaN containing 16% of indium (the third elementary layer).

A first relaxation heat treatment aimed at making the flow layer 8 and the bonding layer 15 flow and at releasing the islands' strains is then carried out. In this example, the step is carried out at 800° C. for 4 hours.

Since the islands 9 of the first group of islands are not strained, their lattice parameter does not change in the course of this heat treatment. The islands of the second and third groups consist of a stack of layers that have different strain levels. The lattice parameter of these islands tends towards the equilibrium lattice parameter of the layer stack that they consist of. The parameter obtained will be close to the lattice parameter of the alloy (In,Ga)N of average composition over the thickness of the stack.

In a subsequent step, the islands are partially etched in order to thin them. The etched thickness is typically to the order of 100 nm. The thickness of the islands is then about 50 to 60 nm. The flowing of the flow layer 8 and of the bonding layer 15 is again caused by the application of a new relaxation heat treatment to release the remaining strains of the islands of the second and third groups. In this case, the conditions of the second heat treatment are identical to those of the first.

The relaxation heat treatment can be renewed, possibly in combination with a thinning of the islands to make their lattice parameters converge toward their target lattice parameter.

In any event, repeating these steps leads to the differentiated relaxation of the island groups and, following these steps, the first group of islands 3a has a lattice parameter typically ranging from 3.180 A to 3.190 A, the second group has a lattice parameter ranging from 3.210 A to 3.225 A and the third group has a lattice parameter ranging from 3.240 A to 3.255 A.

The relaxed or partially relaxed islands 3 are then carried over by bonding on a growth medium 2 provided with an assembly layer 5, e.g., a multilayer of silicon dioxide and nitride. A growth substrate 1 is thus formed. One can proceed with this method similarly to the one in example 1, by making active layers of nitride-based LEDs grow on each of the islands and by completing the manufacture of functional LEDs on the growth substrate, in particular, by forming the LED contacts on either side of the active layers or in the form of a monolithic panel.

### Third Example

A growth substrate 1, comprising a growth medium 2 provided with an assembly layer 5 consisting of a 500 nm stack of silicon oxide in contact with the sapphire medium, 200 nm of silicon nitride and one micron of silicon dioxide, is first prepared. This stack is designed to enable the detachment of the growth medium through laser irradiation in a subsequent step of the method. This growth medium may, for example, consist of a silicon wafer 150 mm in diameter. The growth substrate is composed of three groups of InGaN islands containing 18% of indium. The islands all have a thickness of 40 nm and a square shape of 10 microns on a side. The first group of islands has a lattice parameter of 0.3184 nanometers, the second group has a lattice parameter of 0.3218 nanometers, and the third group has a lattice parameter of 0.3248 nanometers. These target lattice parameters have been chosen so that the collective manufacturing step of the active layers of LEDs leads to the formation of LEDs emitting radiations in the blue, green, and red.

The islands 3 that make up each of these groups are distributed and arranged on the growth medium 2 according to a matrix arrangement in line with what has been disclosed in relation with the description of FIGS. 2a to 2c and the two previous examples.

To manufacture this growth substrate 1, a relaxation substrate 6 comprising a relaxation medium 7, e.g., made of sapphire also 150 mm, and to form a flow layer 8 on it, are first prepared.

The preparation of the flow layer includes first of all the formation of a stripping layer consisting of a stack of 500 nm of silicon oxide in contact with the sapphire medium and of 200 nm of silicon nitride. This stripping stack is designed to enable the detachment of the relaxation medium 7 through laser irradiation in a subsequent step of the method. A first layer of one micron of silicon dioxide is then formed on the stripping layer. Recesses arranged on the surface of the medium are formed in the first layer through lithographic masking and etching to make them correspond to the islands of the second group and bringing the thickness of the first layer of silicon dioxide down to 100 nm. A second layer of about one micron in thickness is then deposited on the surface of the substrate, on the first layer and in the recesses, this second layer consisting of silicon dioxide and a mass proportion of 3% of boron and 4% of phosphorous. Photolithographic masking and etching steps are repeated to form new recesses that are this time arranged on the surface of the substrate to make them correspond to the islands of the third group. Etching is carried out to proceed with the removal of the entire thickness of the second BPSG layer and to preserve a thickness of 100 nm of the first silicon dioxide layer. A third layer consisting of silicon dioxide and a mass proportion of 4% of boron and 4% of phosphorous is then deposited. Lastly, the surface is planarized to partly eliminate the third and second layers so as to form the first, second and third groups of blocks making up the flow layer 8.

The relaxation substrate also includes strained InGaN islands 9, 10 microns square, containing 18% of indium carried over to the flow layer 8 according to a layer transfer method explained in detail in the general description of this disclosure and by making trenches 4. These strained islands 9 are arranged in a similar manner as what has been described above for the relaxed islands 3 of the growth substrate 1. The lattice parameter of these strained islands 9 is of 0.3184 nanometers. Each strained island 9 rests on a block of one of the first, second and third groups thus defining a first, second and third group of strained islands.

The strained islands 9 are coated with an initial GaN stiffening layer 50 nm thick, a residue of a GaN buffer layer of a donor substrate used to realize the relaxation substrate.

A relaxation heat treatment is performed, for example, at 750° C. for one hour. This treatment leads to the lateral expansion of the initially strained islands 9 to form the partially relaxed islands 3. At the relaxation temperature of 750° C., the viscosity of the blocks of the third group is estimated to be about 1E10 N·m⁻²·s⁻¹, that of the blocks of the second group is estimated to be about 4E10 N·m⁻²·s⁻¹, and that of the blocks of the first group, made of silicon dioxide, is not viscous, i.e., they have a viscosity greater than 1E12 N·m⁻²·s⁻¹. Accordingly, following the relaxation heat treatment at 750° C., the relaxation rate of the strains in the islands of the third group is of 90%, they thus have a lattice parameter of 3.246 A. The relaxation rate of the strains in the islands of the second group is of about 50%, i.e., a lattice parameter of 3.218 A. The lattice parameter of the islands of the first group has not changed and remains at 3.184 A.

The estimated viscosity values are only given as examples. For blocks of different compositions or for a different relaxation temperature, the heat treatment time may be adjusted in order for the relaxation rate of the island arranged on the block of intermediate viscosity to range between 40% and 60% at the outcome of the process and for the relaxation rate of an island arranged on a block of lower viscosity to be greater than 70%.

The GaN stiffening layer that coats the partially relaxed islands is then eliminated only through etching and the relaxation heat treatment is renewed under the same conditions as those previously disclosed. Following this treatment, the lattice parameters of the islands of the first, second and third groups are respectively of about 3.184 A, 3.218 A and 3.248 A, i.e., within 0.005 A.

The partially relaxed InGaN islands 3 are then carried over by bonding on a growth medium 2 provided with an assembly layer 5, e.g., a multilayer of silicon dioxide and nitride. One can proceed with this method similarly to the one in example 1 or in example 2, by making active layers of nitride-based LEDs grow on each of the islands and by completing the manufacture of functional LEDs on the growth substrate, in particular, by forming the LED contacts on either side of the active layers or in the form of a monolithic panel.

Of course, the disclosure is not limited to the described embodiments and alternative solutions can be used without leaving the scope of the invention as defined in the claims.

1. A method for manufacturing a plurality of crystalline semiconductor islands having a variety of lattice parameters, the method comprising the following steps:
providing a relaxation substrate comprising a medium, a flow layer disposed on the medium and, arranged on the flow layer, a plurality of crystalline semiconductor islands having the same initial lattice parameter, and comprising a first group of islands having a first lateral expansion potential and a second group of islands having a second lateral expansion potential that is different from the first; and
heat-treating the relaxation substrate at a relaxation temperature that is higher than or equal to the glass transition temperature of the flow layer to cause differentiated relaxation of the islands of the first and second groups, since the lattice parameter of the first group of relaxed islands and that of the second group of relaxed islands then have different values.

2. The manufacturing method of claim 1, wherein, before the heat treatment step, the first group of islands has a first strain level and the second group of islands has a second strain level that is different from the first.

3. The manufacturing method of claim 2, wherein the step of providing the relaxation substrate includes:
forming a stack of elementary crystalline semiconductor layers on a base substrate, the elementary crystalline semiconductor layers having a first area and a second area that have different strain levels;
transferring at least part of the stack to the medium; and
forming trenches in the stack to form the islands of the first group of islands in the first area and to form the islands of the second group of islands in the second area.

4. The method of claim 3, wherein the trenches are formed in the stack after transferring at least part of the stack to the medium.

5. The method of claim 3, wherein forming the stack of elementary crystalline semiconductor layers on the base substrate includes:
forming a plurality of pseudomorphic elementary layers having different compositions; and
removing a portion of the pseudomorphic elementary layers to define the first area and the second area.

6. The method of claim 1, wherein the flow layer comprises a first group of blocks having a first viscosity at the relaxation temperature and a second group of blocks having a second viscosity that is different from the first at the relaxation temperature, the islands of the first group of islands being arranged on the blocks of the first group of blocks and the islands of the second group of islands being arranged on the blocks of the second group of blocks.

7. The method of claim 6, wherein the step of providing the relaxation substrate includes:
forming a first flow layer made of a first material on the medium;
forming at least one recess in the first flow layer;
depositing a second flow layer made of a second material on the first flow layer and in the recess to form a stack of flow layers; and
planarizing the stack of flow layers to eliminate the second layer except for in the recess and to form the first group of blocks and the second group of blocks.

8. The method of claim 1, wherein providing the relaxation substrate includes:
forming the plurality of crystalline semiconductor islands on the flow layer, the plurality of islands having an identical initial strain level; and
selectively treating the strained islands so as to form the first group of strained islands and the second group of strained islands.

9. The method of claim 8, wherein selectively treating the strained islands includes forming a stiffening layer having a first thickness on the first group of strained islands and having a second thickness, which is different from the first thickness, on the second group of strained islands.

10. The method of claim 8, wherein selectively treating the strained islands includes forming, on the first group of strained islands, a stiffening layer comprising a first material and forming, on the second group of strained islands, of a stiffening layer comprising a second material that is different from the first material.

11. The method of claim 8, wherein selectively treating the strained islands comprises reducing a thickness of the strained islands of the first group and/or of the strained islands of the second group, so that the first group and the second group have different thicknesses.

12. The method of claim 10, wherein the heat treatment is carried out at a temperature ranging from 400° C. to 900° C.

13. The method of claim 1, wherein the crystalline semiconductor islands comprise a III-N material.

14. The method of claim 1, further comprising transferring relaxed islands of the first group and relaxed islands of the second group to a growth medium.

15. A growth substrate for forming optoelectronic devices, comprising:
a growth medium,
an assembly layer, and
a first group of crystalline semiconductor islands disposed on the assembly layer and having a first lattice parameter, and
a second group of crystalline semiconductor islands disposed on the assembly layer and having a second lattice parameter that is different from the first lattice parameter.

16. The growth substrate of claim 15, wherein the growth medium comprises a silicon or sapphire wafer.

17. The growth substrate of claim 15, wherein the crystalline semiconductor islands of the first group and the second group comprise InGaN.

18. The growth substrate of claim 15, wherein each island of the first group is located adjacent to an island of the second group, the adjacent islands of the first group and the second group forming pixels.

19. The growth substrate of claim 15, wherein the assembly layer comprises at least one dielectric material.

20. A method of using a growth substrate as recited in claim 15 to collectively manufacture a plurality of optoelectronic devices comprising active layers of various compositions, the method comprising the following steps:
providing the growth substrate; and
exposing the growth substrate to an atmosphere comprising an initial concentration of an atomic element to form a first active layer incorporating the atomic element in a first concentration on the islands of the first group and to form a second active layer incorporating the atomic element in a second concentration, which is different from the first, on the islands of the second group.

21. The method of claim 20, wherein the atmosphere is formed from precursor gases, including TMGa, TEGa, TMIn, and ammonia.

22. The method of claim 21, wherein the atomic element is indium.

23. The method of claim 22, wherein the first and the second active layers comprise an n-doped InGaN layer, a multiple quantum well, or a p-doped InGaN or GaN layer.
